(19) United States
(12) Patent Application Publication
(10) Pub. No.: US 2007/0296078 A1
(43) Pub. Date: Dec. 27, 2007

(54) Semiconductor Module Having Low Thermal Load

(76) Inventors: Mark-Matthias Bakran, Erlangen (DE); Andreas Fuchs, Erlangen (DE); Matthias Hofstetter, Erlangen (DE); Hans-Joachim Knaak, Erlangen (DE); Andreas Nagel, Nurnberg (DE); Norbert Seliger, Zorneding (DE)

Correspondence Address: STAAS & HALSEY LLP, SUITE 700, 1201 NEW YORK AVENUE, N.W., WASHINGTON, DC, 20005, US

(21) Appl. No.: 11/793,919

(22) PCT Filed: Nov. 21, 2005
(86) PCT No.: PCT/EP05/56097

§ 371 Date: Jun. 22, 2007

(30) Foreign Application Priority Data
Dec. 22, 2004 (DE) 10 2004 061 907.7

(51) Int. Cl. H01L 23/36; H01L 23/051

(52) U.S. Cl. 257/712; 257/717; 438/122; 257/E23.101

(57) ABSTRACT

At least one bearing body in a power semiconductor module has a surface section on which a first semiconductor component and at least one additional semiconductor component are arranged adjacent to each other. The semiconductor components have contact surfaces, oriented away from the surface section of the bearing body, that are in a contact in a planar manner to provide a flat connection line between the contact surfaces of the semiconductor components. The flat connection line has a lower inductivity and a lower instance dependency of inductivity compared to a bonding wire. A distance between the semiconductor components along the surface section is greater than a lateral measurement of at least one of the semiconductor components and can be, selectively, relatively large, allowing for thermal and/or temperature expansion and a lower thermal load of the semiconductor module than previously obtained.

### CROSS REFERENCE TO RELATED APPLICATIONS

This application is based on and hereby claims priority to German Application No. 10 2004 061 907.7 filed on Dec. 22, 2004, the contents of which are hereby incorporated by reference.

### BACKGROUND

Described below is a semiconductor module having at least one carrier body and at least two semiconductor components arranged on a surface section of the carrier body.

The semiconductor module is a power semiconductor module, for example. The power semiconductor module has for example a plurality of electrically controllable power semiconductor components that are connected up to one another and combined on one or more carrier bodies (circuit carriers, substrates). An electrically controllable power semiconductor component used in this case is for example a MOSFET (Metal Oxide Semiconductor Field Effect Transistor) or an IGBT (Insulated Gate Bipolar Transistor). These controllable power semiconductor components are distinguished by the fact that high currents in the kA range can be switched. Bonding wires are usually used for the electrical contact-connection of the contacts of the power semiconductor components.

One alternative for the contact-connection of the contacts of the power semiconductor components of a power semiconductor module is known from WO 03/030247 A2, for example. The power semiconductor components are arranged on a substrate. The substrate is for example a DCB (Direct Copper Bonding) substrate having a carrier layer made of a ceramic material to which electrically conductive layers made of copper (copper films) are applied on both sides. The ceramic material is aluminum oxide (Al₂O₃), for example.

The electrical contact-connection of the contacts of the power semiconductor components is effected in planar and large-area fashion. The following procedure is adopted for the electrical contact-connection of a contact of a power semiconductor component: a power semiconductor component is soldered onto one of the electrically conductive layers made of copper of the DCB substrate in such a way that an electrical contact area of the power semiconductor component that faces away from the substrate is present. The power semiconductor component is a MOSFET, for example. The contact area of the MOSFET is a source, gate or drain chip area of the MOSFET. For the electrical contact-connection of the contact area of the power semiconductor component, a polyimide- or epoxide-based plastic film is laminated onto the power semiconductor component and onto the substrate under a vacuum, so that the plastic film is tightly connected to the power semiconductor component and the substrate. The plastic film covers the power semiconductor component and the substrate. A window is subsequently produced in the plastic film where the electrical contact area of the power semiconductor component is situated. The window is produced by laser ablation, for example. The corresponding contact area of the power semiconductor component is uncovered as a result of the production of the window. The electrical contact-connection of the contact area is subsequently effected. For this purpose, a mask is applied on the plastic film, for example, the mask leaving free the contact area and regions of the plastic film for a connecting line toward the contact area. Afterward, a contiguous layer made of an electrically conductive material is produced on the contact area and on the free regions of the plastic film by a plurality of depositions. The connecting line for the electrical contact-connection of the contact area of the power semiconductor component is formed. The result is a power semiconductor module having a multilayer construction composed of electrically insulating and electrically conductive layers.

The power semiconductor components of the known power semiconductor modules are distinguished by a considerable power loss. Therefore, during the operation of the power semiconductor modules, the power semiconductor components experience a high degree of heating and the substrate on which the power semiconductor components are arranged therefore also experiences a high degree of heating. The result is a high thermal load of the semiconductor module. In order to prevent a local overheating, the power semiconductor module must be cooled. It is necessary to provide for an efficient cooling device. This can be realized only with additional outlay.

### SUMMARY

An aspect is a semiconductor module which, during operation, has a lower thermal load in comparison with the related art.

In the embodiments described below, a semiconductor module has at least one carrier body, a semiconductor component arranged on a surface section of the carrier body and having a contact area that is remote from the surface section of the carrier body, at least one further semiconductor component arranged on the surface section of the carrier body and having a further contact area that is remote from the surface section of the carrier body, wherein the semiconductor components are arranged alongside one another on the surface section, the contact area of the semiconductor component and the further contact area of the further semiconductor component are contact-connected in planar fashion, and a distance between the semiconductor components along the surface section is greater than a lateral dimension of at least one of the semiconductor components.

The lateral dimension corresponds to a dimension along an areal extent of the semiconductor component. The lateral dimension is for example a length or a width of the semiconductor component. The distance is preferably less than 0.5 m. In one particular configuration, the distance is selected from the range of 5 mm to 100 mm inclusive, and in particular from the range of 10 mm to 50 mm inclusive. The semiconductor components are arranged in a manner spaced apart from one another. In this case, the distance between the semiconductor components can be chosen to be relatively large. This is possible by virtue of the planar contact-connection. The planar contact-connection is more robust than the contact-connection with bonding wires. Furthermore, in the case of the contact-connection by bonding wires, the distance between semiconductor components to be contact-connected would have to be chosen to be as small as possible since the bonding wires have significantly higher inductances than flat, planar connecting lines and the magnitude of the inductances occurring increases with the length of the bonding wires. However, short bonding wires mean a small distance between the semiconductor components. However, the small distance leads to a high thermal load of the semiconductor module.

The planar contact-connection makes it possible for the semiconductor components to be contact-connected over larger distances without the inductances that occur increasing to the same extent, as in the case of bonding wires. The semiconductor components can be arranged at a larger distance from one another. As a result, heat or temperature spreading occurs during operation of the semiconductor module. Heat does not occur in concentrated fashion, but rather in distributed fashion. The temperature peaks that occur turn out to be lower. By way of example, rather than a single local temperature maximum, a plurality of local temperature maxima which are in return smaller occur. The thermal load of the semiconductor module is significantly reduced by comparison with the related art. Complicated cooling devices for cooling the semiconductor module are no longer necessary.

In accordance with one particular configuration, at least one of the contact areas of the semiconductor components is contact-connected with the aid of an electrical connecting line having a deposition of an electrically conductive material. Deposition should be understood to mean a solid material which arises by separation from a gas phase and/or from a liquid phase. The gas phase and/or the liquid phase are formed by (reactive) mixtures. The deposition is formed from the mixtures. The deposition is a vapor-phase deposition, for example. The vapor-phase deposition is produced for example by a physical deposition method (physical vapor deposition, PVD) or by a chemical deposition method (chemical vapor deposition, CVD). The deposition can also be a liquid-phase deposition. The liquid-phase deposition is an electrodeposition, for example. The electrodeposition includes elemental copper, for example, which is deposited from a solution containing copper ions by electrolysis.

The connecting line for the electrical contact-connection of the contact area of one of the semiconductor components can be connected to an electrical load terminal toward the outside. The contact-connection is effected internally, in particular, that is to say within the semiconductor module. In one particular configuration, therefore, the contact area of the semiconductor component and the further contact area of the further semiconductor component are electrically conductively connected to one another with the aid of the deposition of the electrically conductive material. The two semiconductor components are electrically connected to one another by the connecting line. In this sense it is possible, for example, to replace a single semiconductor component by a plurality of smaller semiconductor components arranged alongside one another, a sum of the active areas of the smaller semiconductor components corresponding to an active area of the single semiconductor component. Through the use of the smaller semiconductor components, heat or temperature spreading is obtained for the same active area.

Efficient temperature spreading is possible for a semiconductor module as described herein, for example a power semiconductor module, which is operated at elevated temperatures; however, it may nevertheless be advantageous to provide for cooling during operation. In one particular configuration, therefore, the carrier body has a cooling device. By way of example, the carrier body in the form of a substrate (for example DCB substrate) is soldered onto a heat sink or is adhesively bonded onto the heat sink with the aid of a thermal conductive adhesive. The heat sink is a copper block, for example. It is also conceivable for the carrier body itself to function as a heat sink for the semiconductor components of the semiconductor module. By way of example, the semiconductor components are applied in electrically insulated fashion to the copper block functioning as a heat sink. By way of example, an electrically insulating but thermally conductive adhesive is used for this purpose.

It is possible to provide for additional heat or temperature spreading by the configuration of the heat sink. For this purpose, the heat sink is not only provided with material having very good thermal conductivity, it is also possible for the form of the heat sink to be chosen in such a way that heat is dissipated very well. In one particular configuration, therefore, the heat sink has a curvature. A surface of the heat sink is curved or cambered. By way of example, the heat sink is provided with cooling fins. It is also conceivable for the heat sink to be a bent or folded copper sheet. The copper sheet functions as a carrier body. Along the surface section of the copper sheet on which the semiconductor components are arranged, the copper sheet has for example one or more curvatures between semiconductor components.

Any desired semiconductor component is conceivable as the semiconductor component. By way of example, the semiconductor component is an LED (Light Emitting Diode). In one particular configuration, at least one of the semiconductor components is a power semiconductor component. Preferably, the power semiconductor component is selected from the group diode, IGBT, MOSFET, thyristor and/or bipolar transistor. The power semiconductor components are combined to form a power semiconductor module. A power switch, for example, used for a power converter is realized with the aid of the power semiconductor module.

To summarize, the following essential advantages are afforded by the semiconductor module described herein:
A semiconductor module is available which, on account of the distance between the semiconductor components, is subjected to a lower thermal load during operation in comparison with a semiconductor module of the related art.
The relatively large distance is possible on account of the planar connecting technique that leads to higher EMC compatibility in comparison with bonding wires or to a reduction of overvoltage spikes during operation.
The semiconductor module can be operated with a larger active area of the semiconductor components and thus with a higher power for approximately the same thermal load in comparison with a known semiconductor module.
On account of the lower thermal load, it is possible to use a cooling device having a lower cooling capacity in comparison with the known art.

### BRIEF DESCRIPTION OF THE DRAWINGS

These and other objects and advantages will become more apparent and more readily appreciated from the following description of exemplary embodiments, taken in conjunction with the accompanying drawings which are schematic and not true to scale and of which:

FIG. 1 shows a semiconductor module in a lateral cross section.

FIG. 2 shows a detail from the semiconductor module in a lateral cross section.

FIG. 3 shows a further semiconductor module in a lateral cross section.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The exemplary embodiments relate in each case to a semiconductor module in the form of a power semiconductor module 1. The power semiconductor module 1 has a power semiconductor component 12 having a contact area 121 and at least one further power semiconductor component 13 having a further contact area 131. The power semiconductor components 12 and 13 are IGBTs. In accordance with alternative embodiments, the power semiconductor components 12 and 13 are MOSFETs. The contact areas 121 and 131 of the power semiconductor components 12 and 13 are contact-connected in large-area fashion.

The power semiconductor components 12 and 13 are applied on a surface section 111 of a carrier body 11. The carrier body 11 is a DCB substrate. The DCB substrate has a carrier layer 112 made of aluminum oxide and electrical conduction layers 113 and 114 made of copper that are applied on both sides (cf. FIG. 2).

The power semiconductor component 12 and the further power semiconductor component are soldered on the surface section 111 of the DCB substrate 11 that is provided by the conduction layer 113. A solder layer 116 results in each case. In this case, the distance 15 between the power semiconductor components 12 and 13 along the surface section 111 of the carrier body 11 is greater than a lateral dimension 123 of the power semiconductor component 12 and a further lateral dimension 133 of the further power semiconductor component 13. Efficient heat or temperature spreading is obtained as a result.

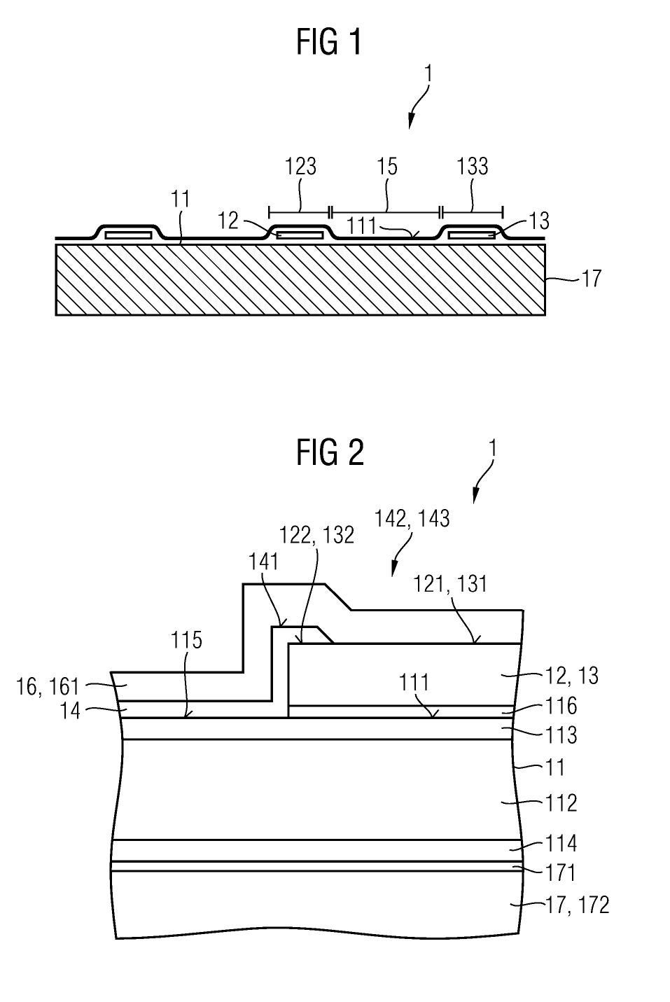

In order to improve the heat or energy spreading, in accordance with a first embodiment, the DCB substrate 11 is soldered on a heat sink 17 (cf. FIG. 1). The heat sink 17 is made of copper. The DCB substrate 11 is soldered onto the heat sink 17 by the further conduction layer 114. This results in a solder layer 171 between the DCB substrate 11 and the heat sink 17.

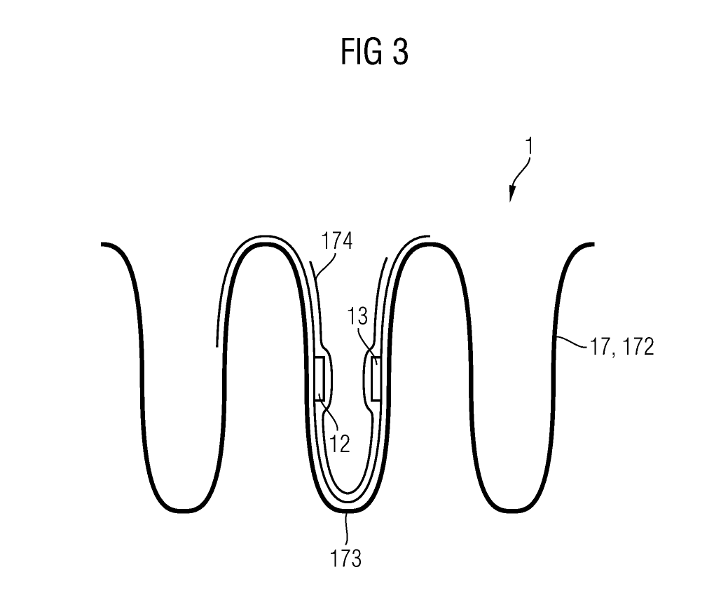

In accordance with a further embodiment, each of the power semiconductor components 12 and 13 is applied on a respective DCB substrate (cf. FIG. 3). The DCB substrates are soldered on a folded copper sheet 172. The folded copper sheet 172 has at least one curvature 173 between the power semiconductor components 12 and 13. This results in a heat sink 17 having a relatively large surface area. By conducting a cooling fluid past the folded copper sheet 172, it is possible to provide for efficient heat and temperature spreading. For electrical insulation, a covering film 174 is laminated on over the power semiconductor components 12 and 13 and the electrical connecting lines thereof.

The power semiconductor components 12 and 13 are soldered onto the DCB substrate 11 or onto the DCB substrates 11 in such a way

that the contact area 121 of the power semiconductor component 12 and the further contact area 131 of the further power semiconductor component 131 face away from the DCB substrate 11.

For the large-area, planar electrical contact-connection of the contact areas 121 and 131, an insulation film (plastic film) 14 is laminated on under vacuum. In this case, the insulation film 14 is laminated onto the DCB substrate 11 and the power semiconductor components 12 and 13 in such a way that a surface contour 122 of the power semiconductor component 12, a further surface contour 132 of the further power semiconductor component 13 and a surface contour 115 of the DCB substrate 11 are reproduced in a surface contour 141 of the insulation film 14 which faces away from the DCB substrate 11 and the power semiconductor components 12 and 13. The topography resulting from the power semiconductor component 12, the further power semiconductor component 13 and the DCB substrate 11 is modeled by the insulation film 14.

The following procedure is adopted for producing the power semiconductor module 1: firstly, an arrangement composed of the power semiconductor components 12 and 13 is provided on the substrate 11 or on the substrates 11. A plastic film 14 is subsequently laminated on under vacuum. The contact area 121 of the power semiconductor component 12 and the further contact area 131 of the further power semiconductor component 13 are uncovered by opening the window 142 and the further window 143 in the plastic film 14. The windows 142 and 143 are opened by laser ablation. A planar electrical contact-connection of the contact area 121 and of the further contact area 131 is subsequently effected. In accordance with a first embodiment, the contact areas 121 and 131 are electrically conductively connected to one another. An electrical connecting line 16 is produced between the contact areas 121 and 131. For this purpose, a deposition 161 is produced on the contact areas 121 and 131 and on the plastic film 14. Electrically conductive material is deposited.

The deposition 161 has a multilayer construction (not illustrated). It has a plurality of partial metal depositions which each inherently perform different functions. A first partial deposition made of titanium functions as an adhesion promoting layer, a second partial deposition made of a titanium-tungsten alloy functions as a diffusion barrier, and a third partial deposition made of copper functions as a seed layer. These three partial depositions are deposited by a vapor deposition method in each case. The layer thicknesses of the partial depositions are a few nm to a few μm. Finally, copper is deposited electrolytically on the seed layer.

In accordance with an embodiment that is not illustrated, each of the contact areas 121 and 131 of the power semiconductor components 12 and 13 is electrically conductively connected to a respective external load terminal via a respective electrical connecting line.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-9. (canceled)

10. A semiconductor module, comprising:
at least one carrier body having a surface section;
a semiconductor component arranged on the surface section of said carrier body and having a first contact area that is remote from the surface section of the carrier body; and
at least one additional semiconductor component arranged on the surface section of the carrier body alongside said semiconductor component but separated by a distance along the surface section that is greater than a lateral dimension of at least one of the semiconductor components, and is between 5 mm and 100 mm inclusive, said at least one additional semiconductor component having a second contact area that is remote from the surface section of the carrier body and is electrically conductively connected to the first contact area of the semiconductor component by a connecting line formed by deposition of an electrically conductive material.

11. The semiconductor module as claimed in claim 10, wherein the distance between the semiconductor components is between 10 mm to 50 mm inclusive.

12. The semiconductor module as claimed in claim 11, wherein the carrier body includes a cooling device.

13. The semiconductor module as claimed in claim 12, wherein the cooling device includes a heat sink.

14. The semiconductor module as claimed in claim 13, wherein the heat sink has at least one curvature.

15. The semiconductor module as claimed in claim 14, wherein at least one of the semiconductor components is a power semiconductor component.

16. The semiconductor module as claimed in claim 15, wherein the power semiconductor component is one of a group diode, an insulated gate bipolar transistor, a metal oxide semiconductor field effect transistor, a thyristor and a bipolar transistor.
